(19) United States
(12) Patent Application Publication
(10) Pub. No.: US 2018/0164353 A1
(43) Pub. Date: Jun. 14, 2018

(54) PLATFORM FOR DYEING INDUSTRY COMPRISING FACTORY ENERGY MANAGEMENT SYSTEM LINKED WITH OPTIMIZED PRODUCTION MANAGEMENT SYSTEM

(71) Applicant: SEJOONGIS CO., LTD., Daegu-si (KR)

(72) Inventor: Jin Hyun SEOL, Daegu-si (KR)

(73) Assignee: SEJOONGIS CO., LTD., Daegu-si (KR)

(21) Appl. No.: 15/837,260

(22) Filed: Dec. 11, 2017

Related U.S. Application Data
(60) Provisional application No. 62/432,550, filed on Dec. 9, 2016.

(51) Int. Cl. G01R 21/133; G01R 21/14

(52) U.S. Cl. CPC G01R 21/1331; G01R 21/14

(57) ABSTRACT

The present invention relates to a platform for the dyeing industrial, comprising a factory energy management system linked with an optimized production management system, in which the platform enables an energy management system (EMS) to be applied to dyeing industrial processes that over-consume energy, so that the consumption of energy can be reduced by an optimized production management process, whereby the proportion of energy cost in the production cost can be reduced, thereby ensuring industrial competitiveness. The platform according to the present invention comprises a communication interface platform, an energy optimization technology analysis platform, and a monitoring and analysis status platform.

CROSS REFERENCE TO RELATED APPLICATION(S)

This patent application claims priority to and the benefit of U.S. Provisional Patent Application No. 62/432,550, filed Dec. 9, 2016 in the U.S. Patent and Trademark Office, the entire contents of which are incorporated herein by reference.

### BACKGROUND OF THE INVENTION

### Field of the Invention

The present invention relates to a platform for the dyeing industrial, comprising a factory energy management system linked with an optimized production management system, and more particularly to a platform for the dyeing industrial, comprising a factory energy management system linked with an optimized production management system, in which the platform enables an energy management system (EMS) to be applied to dyeing industrial processes that over-consume energy, so that the usage of energy can be monitored in real time by an optimized production management process, and the energy use of each process can be systematically optimized by data analysis, whereby the overall consumption of energy in the dyeing industry can be reduced to reduce the proportion of energy cost in the production cost, thereby ensuring industrial competitiveness.

### Description of the Prior Art

Generally, dyeing and fmishing processes include a pretreatment process (a roll taping machine, a singeing machine, a refining machine, a water washing machine, a dewatering machine, etc.), a dyeing process (a jet flow dyeing machine, a CPB dyeing machine, an atmospheric dyeing machine, a jigger dyeing machine, etc.), a tenter process (a tenter machine, a dryer, etc.), a fmishing process (a coating machine, a liquid ammonia machine, a hot-melt lighting machine, a mercerizing machine, etc.), and an inspection process (an inspection machine, etc.).

The dyeing industry is over-consuming energy in all the processes, and the proportion of energy cost in the production cost is 30 to 50%. Furthermore, the dyeing industry uses various energy sources due to the characteristics thereof Specifically, 77% of total fuel use and 54% of total electricity use are for equipment driving, and the amount of energy consumed is larger in the order of steam, electricity and LNG. Processes including a dyeing machine and a fmishing machine, which use the largest amount of a heat source (steam or LNG), account for 90% or more of total energy consumption. In particular, steam or LNG, which is used as a heat source, is major energy in the dyeing industry, and is used as a heating fuel in all the processes.

However, South Korea relies on imports for 95% of its total energy consumption, and about 62% of this energy is consumed in industrial applications. Thus, there is an urgent need to reduce such industrial energy consumption.

Therefore, there is a need for an energy management technology that can contribute to cost reduction and cost competitiveness by managing the amount of heat source used in the dyeing industry and optimizing the energy source according to the user's working environment.

### PRIOR ART DOCUMENTS

### Patent Documents

(Patent Document 1) KR 10-2015-0043169 A (published on Apr. 22, 2015).

(Patent Document 2) KR 10-2016-0063892 A (published on Jun. 7, 2016).

### SUMMARY OF THE INVENTION

Therefore, the present invention has been made in order to solve the above-described problems, and it is an object of the present invention to provide a platform for the dyeing industrial, comprising a factory energy management system linked with an optimized production management system, in which the platform enables an energy management system (EMS) to be applied to dyeing industrial processes that over-consume energy, so that the consumption of energy can be reduced by an optimized production management process, whereby the proportion of energy cost in the production cost can be reduced, thereby ensuring industrial competitiveness.

To achieve the above, in one embodiment, the present invention provides a platform for the dyeing industrial, comprising a factory energy management system linked with an optimized production management system, the platform comprising a communication interface platform, an energy optimization technology analysis platform, and a monitoring and analysis status platform, wherein the communication interface platform comprises a barcode for monitoring the flow of a production line, a temperature sensor for measuring the load of equipment, a measuring device (instrument) related to communication with a measuring device for measuring energy supply required for operation of the production line, an application for collecting/monitoring the data of the sensor, and an application for linking with other systems; the energy optimization technology analysis platform comprises an internal process to which settings and algorithms for performing analysis through energy efficiency optimization technology are applied; and the monitoring and analysis status platform comprises a module for real-time monitoring of energy usage and equipment operation status collected from the instrument/sensor, and a module for displaying analysis contents obtained through energy efficiency optimization technology.

### BRIEF DESCRIPTION OF THE DRAWINGS

FIG. 1 is a block diagram showing the configuration of the platform of a factory energy management system (FEMS) for the dyeing industry according to one embodiment of the present invention.

FIG. 2 is a schematic diagram showing the configuration of an FEMS solution according to the present invention.

FIG. 3 is a block diagram showing the configuration of a target system according to the present invention.

FIG. 4 illustrates a main screen that is embodied in a factory energy management system (FEMS) for the dyeing industry according to one embodiment of the present invention.

FIG. 5 is a reference view illustrating a sensing information collection process in a factory energy management system (FEMS) for the dyeing industry according to one embodiment of the present invention.

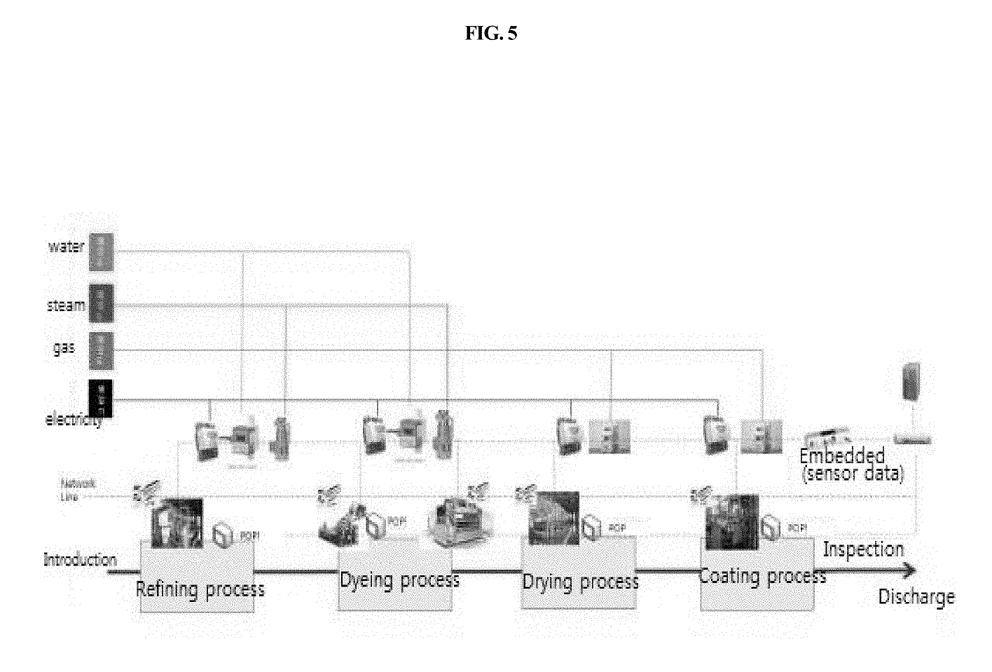

FIG. 6 is a reference table illustrating a data analysis method that may be used in the present invention.

FIG. 7 shows dyeing curve graphs illustrating the present invention.

FIG. 8 is a graph showing the analysis of an optimized process, which illustrates the present invention.

FIG. 9 is a graph showing the energy reduction by dyeing machine dyeing curve analysis, which illustrates the present invention.

FIG. 10 is a graph showing the energy reduction by tenter dwell time analysis, which illustrates the present invention.

### DETAILED DESCRIPTION OF THE INVENTION

Hereinafter, the overall configuration and operation of a factory energy management system for the dyeing industry according to the present invention will be described with reference to the accompanying drawings.

The terms and words used in the specification and claims should not be interpreted as being limited to typical meanings or dictionary definitions, but should be interpreted as having meanings and concepts relevant to the technical scope of the present invention, based on the principle according to which the inventors can appropriately define the concept of the terms to describe their invention in the best manner. Accordingly, it should be understood that the embodiments described in the specification and the configurations shown in the drawings are merely examples, and thus there may be various equivalents and modifications capable of replacing them at the time of filing of the present application.

A factory energy management system (FEMS) for the dyeing industry according to one embodiment of the present invention is a solution that optimizes the use of energy by monitoring the usage of energy in real time based on hardware, software and ICT-based monitoring and control technology and analyzing aggregate data The FEMS solution is configured to apply energy use factors and related data analysis and control processes in different manners depending on the characteristics of dyeing industrial processes. Also, the FEMS solution provides a platform comprising an energy management system (EMS) integrated with an optimized production management system (POP). The platform is linked with production optimization technology so that energy demand forecasting enables energy savings. Furthermore, through this linkage, work and energy management monitoring becomes possible; graphic design facilitates energy goal management and the analysis of production management workflows; matrix-form design facilitates main monitoring of energy and production management; a design comprising a combination of graphic and list forms facilitate process analysis; and calculation input window and bar graph finishing design make demand forecasting tailored to the user.

FEMS Platform Design

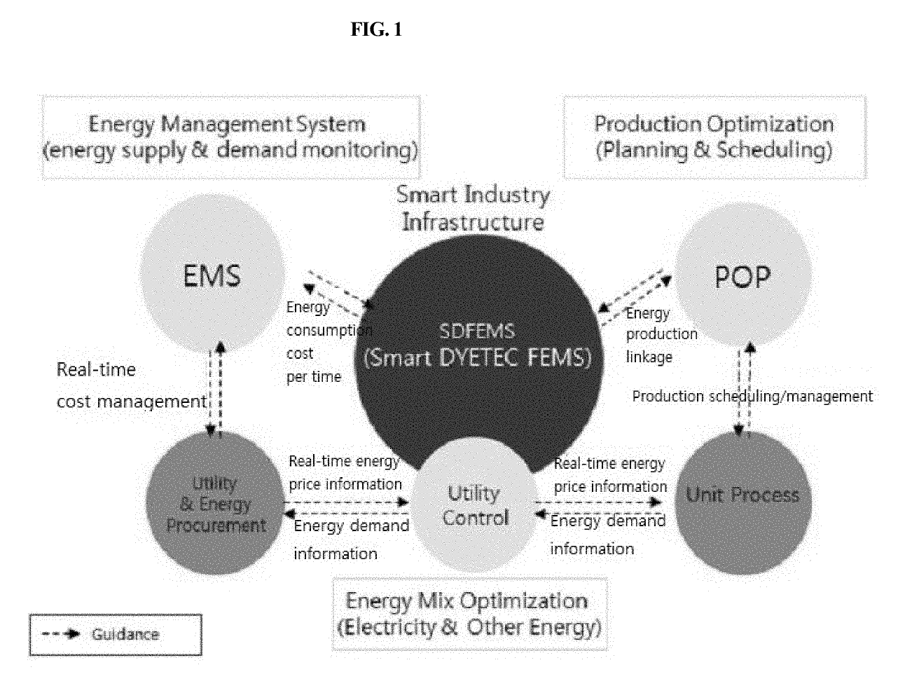

As illustrated in FIG. 1, the FEMS platform may comprise a communication interface platform, an energy optimization technology analysis platform, and a monitoring and analysis status platform.

The communication interface platform is configured for instruments, meters, sensors, etc., and may comprise: a barcode for monitoring the flow of a production line; a temperature sensor for measuring the load of equipment; a measuring device (instrument) related to communication with a measuring device for measuring energy supply required for operation of the production line; an application for collecting/monitoring the data of the sensor, and an application for linking with other systems.

The energy optimization technology analysis platform may comprise an internal process to which settings and algorithms for performing analysis through energy efficiency optimization technology are applied.

The monitoring and analysis status platform may be configured to include a module for real-time monitoring of energy usage and equipment operation status collected from the instrument/sensor, and a module for displaying analysis contents obtained through energy efficiency optimization technology.

FEMS Solution

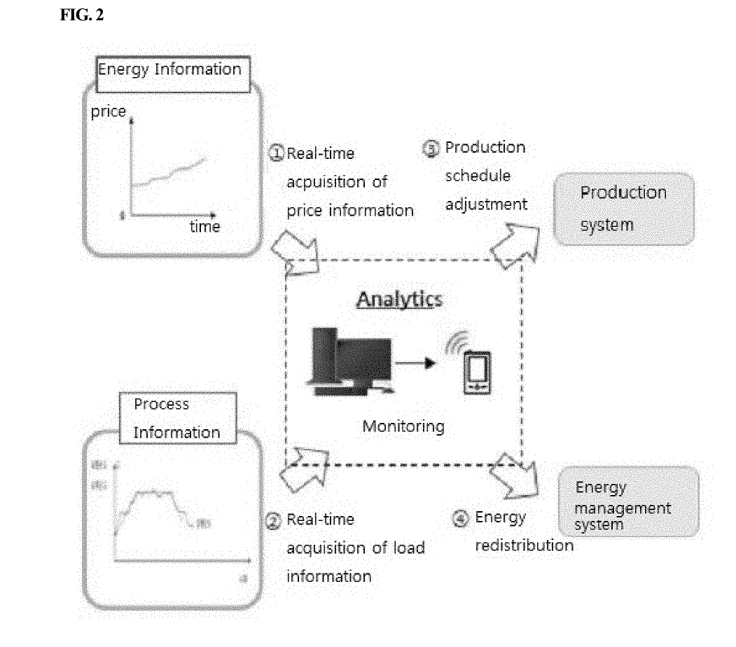

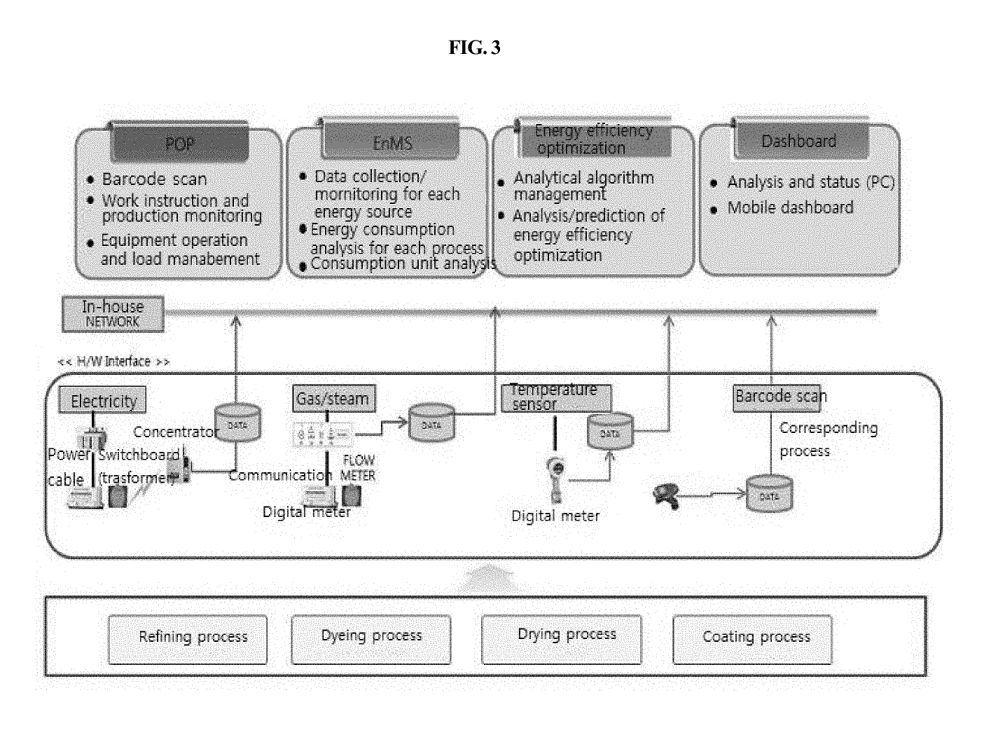

The FEMS solution includes: a module that applies the product production and production time to the barcode of the process to determine the input time and quantity, as illustrated in FIG. 2; a function of analyzing equipment load information using a temperature sensor attached to the equipment, in order to determine whether the process is normally operating according to a work instruction; a function of analyzing the energy usage collected from the measuring instrument related to the energy source and analyzing the energy usage pattern of the equipment put into production; a function of managing various operation patterns (Pareto, time series, control chart, predictive analysis), analyzing the status of equipment operation according to actual production, and analyzing the optimization of energy use efficiency for equipment operation to make the result and prediction of optimal conditions to reduce energy use; a dash board that allows the analyzed and monitored content to be viewed on mobile; an open application that easily collects information related to production equipment to enable analysis through linkage with an existing ERP/POP system; and the like. The configuration of a target system based on this solution is as illustrated in FIG. 3.

Manual and Guide

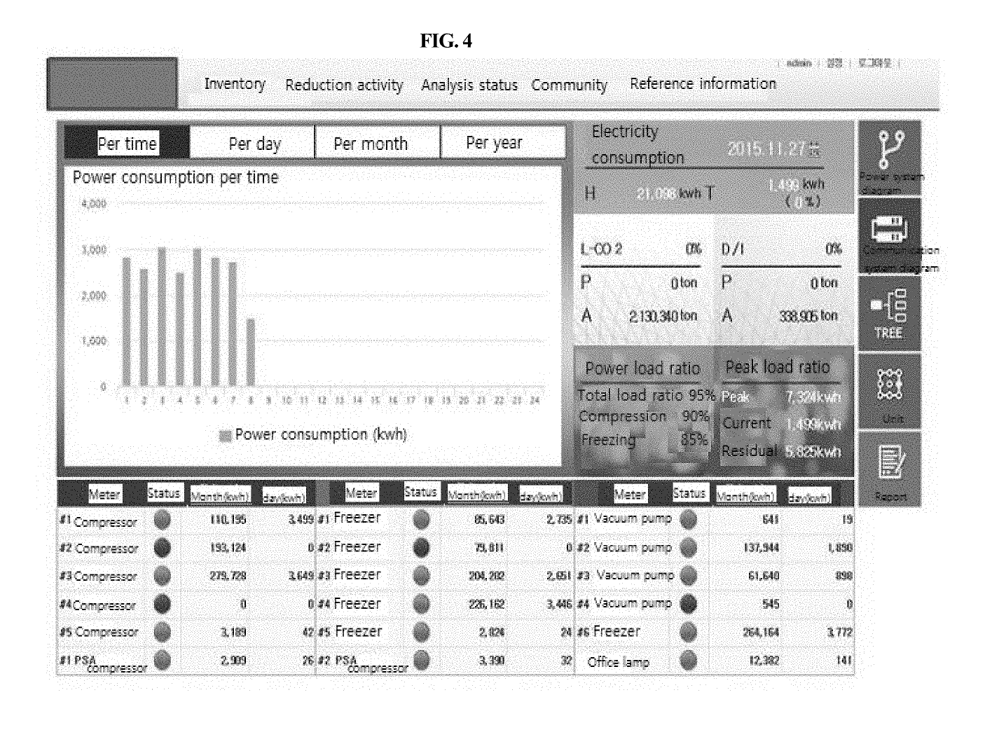

As shown in FIG. 4, for manuals and guides, the manual of a main screen is designed to facilitate management for each energy source and production. In addition, the main screen is composed of sort functions based on the main functions for each menu tool, so that the linkage between production and energy can be improved. The main screen forms are configured according to OA function compatibility for easy report creation and output.

The FEMS installation verification guide is set to a guide based on the proportion of the measured energy in the energy to be measured, a measurement guide based on external energy and internal energy, a measurement guide for the main process line and major equipment, a guide for data and a collection method and reliability conditions, a guide for data time series and correlation analysis, a guide for definitions for energy and process units, indicators for monitoring, targets and performance indicators, a systematic guide for each energy source and process factor, or the like.

Sensing Information Collection

For sensing information collection, data collected from the database of the DYETEC Institute are used for analyzed, and data for the physical properties of fibers (polyester, nylon) and for process conditions (temperature, speed, operation time, input staffs, utilities, etc.) are created and combined.

In addition, data are used for data analysis for each sensor and each measurement item, and the measurement items are set up to measure each process temperature and each process energy source (electricity, steam, water, etc.). Measurement of each process temperature and each energy source is performed in the order of transmission of sensor contact to embedded of each process→embedded (sensor DB)→server.

Data Analysis and Interpretation

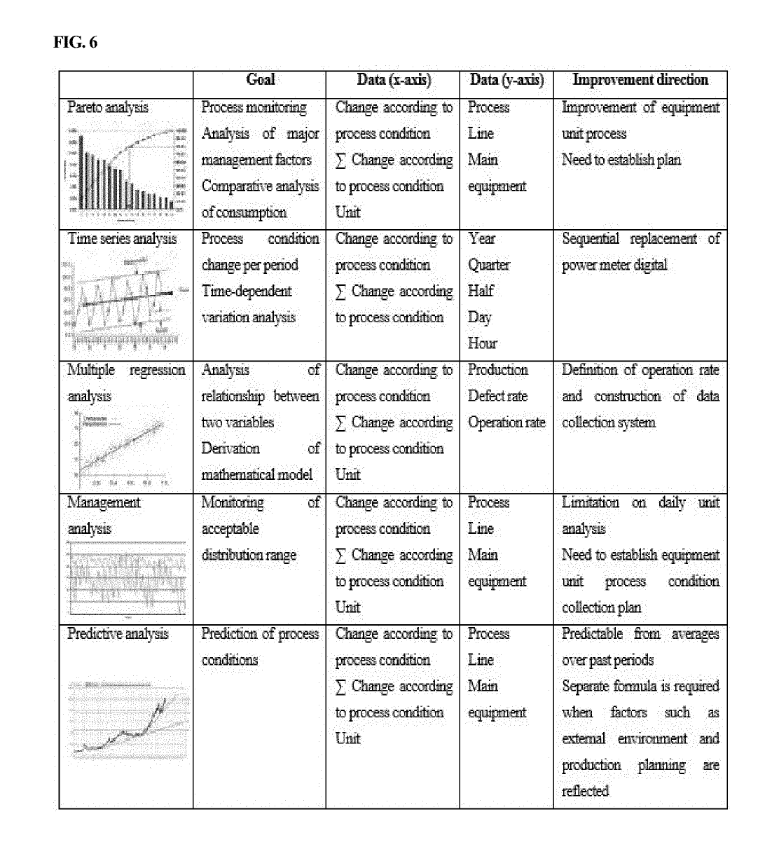

For the analysis and interpretation of data, advanced statistical techniques are used, including various analyzes and basic monitoring based on collected process data In addition, energy data analysis is used to derive management targets, and standardization and energy increase factors are analyzed and used as various types of forecast data Such a data analysis method is illustrated in FIG. 6, and interpretation can be performed by analyzing correlation between process factors and energy factors. For the analysis of correlation between process factors and energy factors, analysis of steam change according to temperature rise of a dyeing machine, analysis of gas change quantity according to maintained temperature of a tenter, analysis of RPM variation and electricity quantity according to tenter speed variation, analysis of steam change according to dyeing machine pressure change, etc. can be performed. The interpretation by analysis of correlation analysis between process factors and energy factors is to derive numerical formulations that can convert process factors into energy factors through correlation analysis, and it is possible to reduce the number of sensing contacts by calculating the predicted capacity of steam, gas, electricity, water, and the like, based on process factors. The necessity of this correlation analysis is to replace the energy factors sensing with the process factor sensing to reduce the sensing contact point. That is, it is intended to reduce the cost of sensing construction.

Test-Bed Construction and Design Test-bed construction and design can be done by building test beds related to a dyeing machine and a tenter. The construction of the test beds related to the dyeing machine and the tentering machine can be made by installing the dyeing machine utility and the temperature-related sensor, and installing the network for dyeing sensor→embedded→server interworking. The construction of the test bed related to the tenter can be accomplished by installing the tenter utility and the temperature-related sensor, and installing the network for the tenter sensor→embedded→server interworking.

Architecture Design

Architecture design can be achieved through systematic establishment of the optimum utilization rate of equipment by analyzing the dyeing curve of a dyeing process dyeing machine and analysis of process conditions by fiber properties.

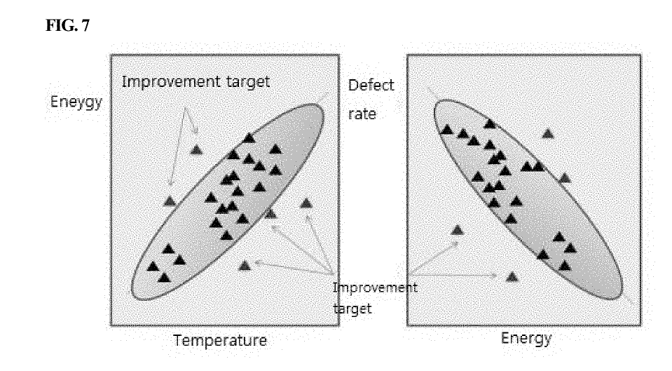

In the case of systematic establishment of the optimum utilization rate of the equipment through the analysis of the dyeing curve of the dyeing process dyeing machine, the dyeing curve is a curve of the coloring relationship between fiber fabric and dye as illustrated in FIG. 7. In particular, the adsorption rate of the dye varies with the change of temperature, and it varies depending on the properties of fiber. Thus, when the change of the dialysis curve according to the physical properties of the fiber material is analyzed to establish the optimum utilization rate of the equipment, it is possible to reduce the rise time to the highest temperature of the adsorption rate of the fiber material and derive the appropriate temperature with high adsorption rate, thereby reducing energy. For example, by reducing the rise time to warming temperature from 10 min (existing) to 8 min (after improvement), it is possible to save the power energy source, and by reducing the temperature of the dyeing section of dye from 72° C. (existing) to 68° C. (after improvement), steam energy sources can be saved.

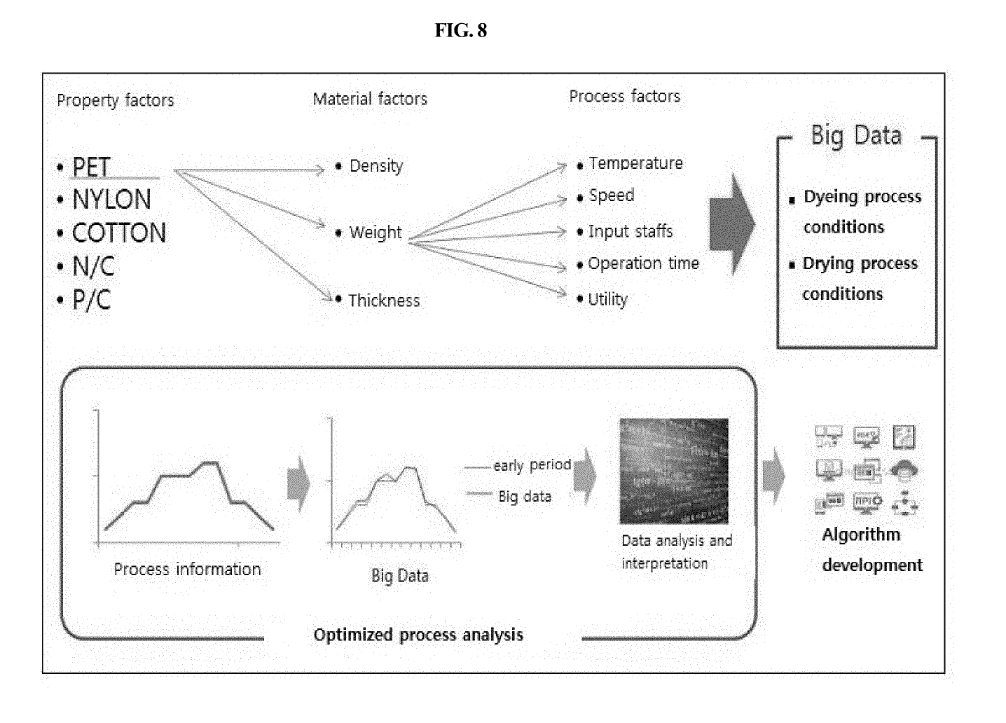

In the case of the architecture design based on the analysis of process conditions according to fiber properties, as illustrated in FIG. 8, big data analysis and configuration through applied property factor, material factor and process factor, data analysis and items for each factor are defined, and mathematical modeling formula by a data analysis method for a major process (dyeing, drying) is applied.

Standard Platform Demonstration Test

Standard platform demonstration is made possible by verifying the platform efficiency of the dyeing process dyeing machine and verifying the platform efficiency of the drying process tenter.

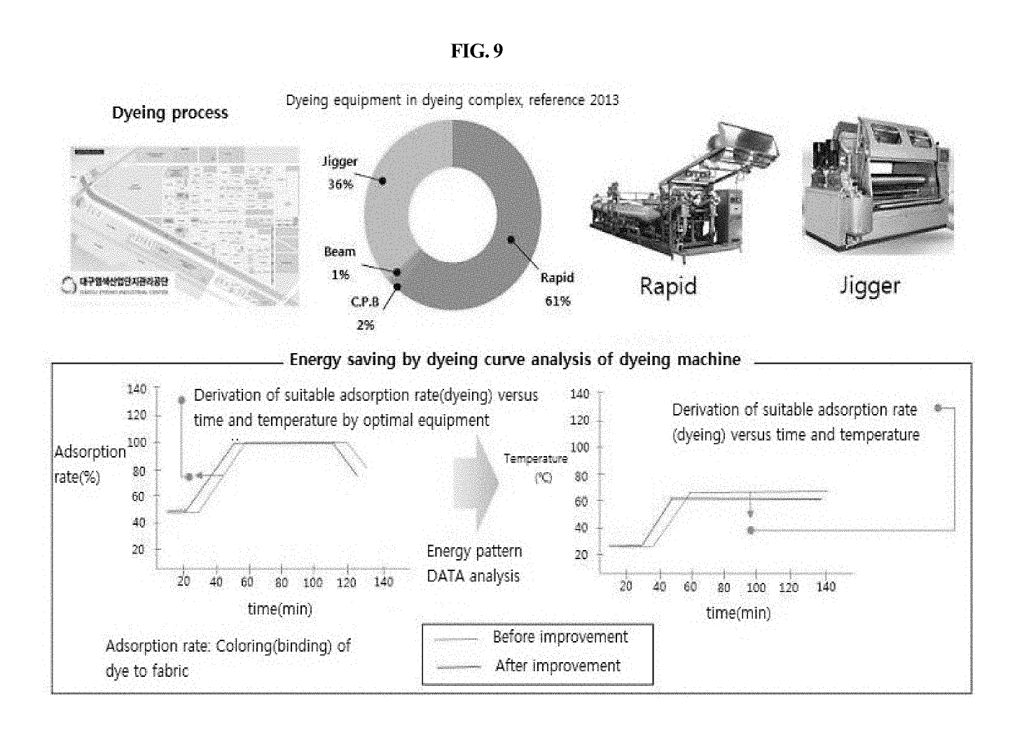

That is, in the case of the platform efficiency verification of the dyeing process dyeing machine, the change of the dyeing curve according to the properties of the fiber material is analyzed to establish the optimum equipment utilization rate system. As a result, it is possible to reduce the rise time to the highest temperature at which the adsorption rate of fibrous material is the highest and to derive the appropriate temperature at which the adsorption rate is high, and thus energy can be saved by analyzing the dyeing curve as illustrated in FIG. 9.

In order to derive such optimal equipment utilization rate, it is necessary to accumulate sufficient process performance data and energy source data, and data acquisition through a simulator under the same conditions is required.

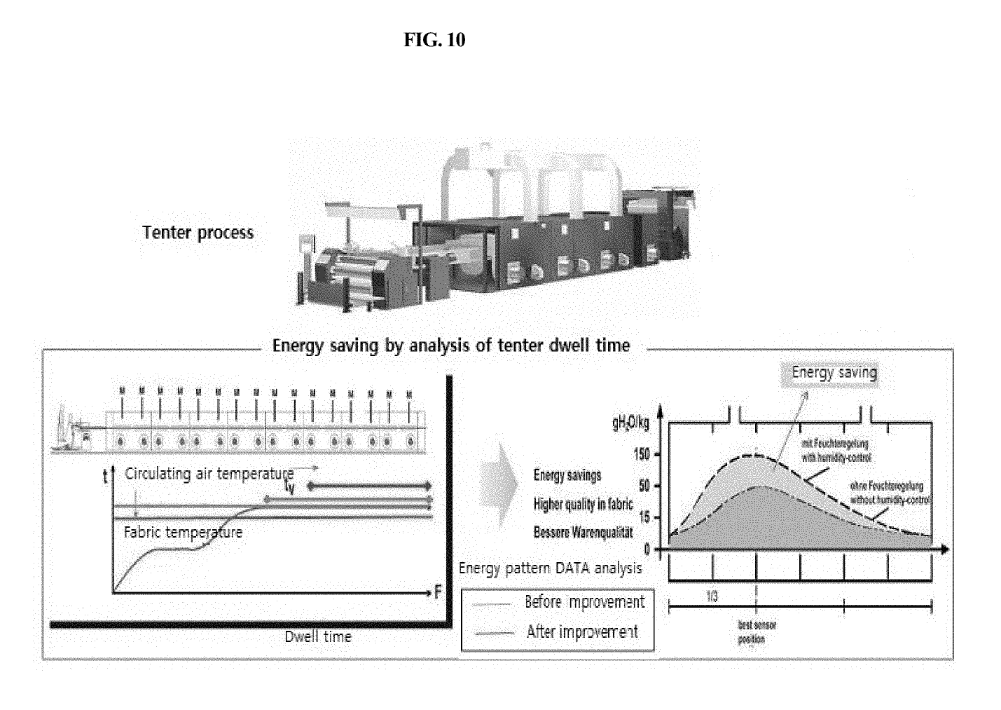

In the case of verifying the platform efficiency of the drying process tenter, the wetting rate of fabric differs according to the properties of the fiber material, and the degree of wetting in the dehydration process varies depending on the fabric section. Thus, as illustrated in FIG. 10, the energy saving system is established by analyzing the dwell time (time at which the fabric stays at a certain temperature) in the tenter process, which is a fixing process that restores the shrunk fabric to the original fabric form by drying the wetted fabric after dyeing. For example, since the main components of the dwell time are the temperature and the operating speed, the temperature is changed from 280° C. (existing) to a temperature between 220° C. and 280° C. (after improvement), and the operating speed can be changed from 60 M/min (existing) to 60-85 M/min (after improvement), thereby reducing energy.

In order to derive the optimum equipment utilization rate system, it is necessary to accumulate sufficient process performance data and energy source data, and also to acquire data through a simulator under the same conditions.

As described above, according to the present invention, there is an advantage in that energy can be saved through the prediction of energy demand by use of an optimized production management system (POP) linked with an energy management system (EMS). In addition, there is an advantage in that graphical design and the like facilitate energy target management, production management, process analysis, monitoring of work management, and flow analysis.

Although the preferred embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A platform for dyeing industrial, comprising a factory energy management system linked with an optimized production management system, the platform comprising a communication interface platform, an energy optimization technology analysis platform, and a monitoring and analysis status platform, wherein
the communication interface platform comprises a barcode for monitoring the flow of a production line, a temperature sensor for measuring the load of equipment, a measuring device (instrument) related to communication with a measuring device for measuring energy supply required for operation of the production line, an application for collecting/monitoring the data of the sensor, and an application for linking with other systems;
the energy optimization technology analysis platform comprises an internal process to which settings and algorithms for performing analysis through energy efficiency optimization technology are applied; and
the monitoring and analysis status platform comprises a module for real-time monitoring of energy usage and equipment operation status collected from the instrument/sensor, and a module for displaying analysis contents obtained through energy efficiency optimization technology.
